(19) United States
(12) Patent Application Publication
(10) Pub. No.: US 2024/0255440 A1
(43) Pub. Date: Aug. 1, 2024

(54) ABNORMALITY DETECTION METHOD FOR PRESET SPECTRUM DATA FOR USE IN MEASURING FILM THICKNESS, AND OPTICAL FILM-THICKNESS MEASURING APPARATUS

(71) Applicant: EBARA CORPORATION, Tokyo (JP)

(72) Inventor: Yuki WATANABE, Tokyo (JP)

(21) Appl. No.: 18/419,952

(22) Filed: Jan. 23, 2024

(30) Foreign Application Priority Data
Jan. 27, 2023 (JP) 2023-010835

(51) Int. Cl. G01N 21/95; G01B 11/06

(52) U.S. Cl. CPC G01N 21/9501; G01B 11/0633; G01B 2210/56; G01N 2201/1293; G01N 2201/1296

(57) ABSTRACT

An abnormality detection method that can automatically detect abnormality in preset spectrum data, such as reference intensity data (base intensity data) used for optical measurement of a film thickness is disclosed. The abnormality detection method includes: creating the preset spectrum data before polishing of the workpiece; inputting the preset spectrum data to an autoencoder which is a trained model constructed by machine learning using training data including a plurality of normal preset spectra data; calculating a difference between output data output from the autoencoder and the preset spectrum data; and determining that there is an abnormality in the preset spectrum data when the difference is larger than a threshold value.

### CROSS REFERENCE TO RELATED APPLICATION

This document claims priority to Japanese Patent Application No. 2023-010835 filed Jan. 27, 2023, the entire contents of which are hereby incorporated by reference.

### BACKGROUND

A manufacturing process for a semiconductor device includes various processes, such as a process of polishing a dielectric film (e.g., SiO₂) and a process of polishing a metal film (e.g., copper or tungsten). Manufacturing processes for a back-illuminated CMOS sensor and a through-silicon via (TSV) include a process of polishing a silicon layer (or a silicon wafer) in addition to the process of polishing the insulating film or the metal film. Polishing of a wafer is terminated when a thickness of a film (e.g., dielectric film, metal film, silicon film) that forms a surface of the wafer has reached a predetermined target value.

Polishing of the wafer is performed using a polishing apparatus. In order to measure a thickness of a non-metal film, such as a dielectric film or a silicon layer, the polishing apparatus generally includes an optical film-thickness measuring device. This optical film-thickness measuring device is configured to direct light, emitted by a light source, to the surface of the wafer and analyze a spectrum of reflected light from the wafer to detect a film thickness of the wafer.

In optical film-thickness measurement, there may be individual variation in optical system. In other words, an intensity of light may vary due to individual variation in optical system, which causes an unwanted noise. Therefore, in order to remove such a noise caused by the optical system, reference intensity data (base intensity data) are measured in advance, and a measured intensity at each wavelength of reflected light during wafer polishing is divided by a reference intensity, so that relative reflectance is determined. Using the relative reflectance can remove the noise caused by the optical system and can allow for accurate measuring of a film thickness.

If there is an unpredictable defect in the optical system or an unpredictable setup error during device startup or device adjustment, the reference intensity data may contain abnormal values, resulting in a large error in an actual measurement value. Therefore, conventionally, it has been determined whether or not an abnormality in the reference intensity data exists based on actual film-thickness measurement results when starting up of the device is performed or consumables, such as polishing pad, are replaced. However, such conventional practice requires a long time and labor.

### SUMMARY

Therefore, there are provided an abnormality detection method and an optical film-thickness measuring apparatus that can automatically detect abnormality in preset spectrum data, such as reference intensity data (base intensity data) used for optical measurement of a film thickness.

Embodiments, which will be described below, relate to a technique for measuring a film thickness based on a spectrum of reflected light from a workpiece, such as wafer, substrate, or panel, for use in manufacturing of semiconductor devices, and more particularly to a technique for detecting abnormality of preset spectrum data prepared in advance for measuring of a film thickness.

In an embodiment, there is provided an abnormality detection method for preset spectrum data used for optically measuring a film thickness of a workpiece, comprising: creating the preset spectrum data before polishing of the workpiece; inputting the preset spectrum data to an autoencoder which is a trained model constructed by machine learning using training data including a plurality of normal preset spectra data; calculating a difference between output data output from the autoencoder and the preset spectrum data; and determining that there is an abnormality in the preset spectrum data when the difference is larger than a threshold value.

In an embodiment, the abnormality detection method further comprises: classifying a plurality of preset spectra data acquired in the past into groups according to algorithm of clustering; producing the training data including a plurality of normal preset spectra data belonging to one of the groups; and performing the machine learning using the training data to construct the autoencoder which is the trained model.

In an embodiment, the preset spectrum data is one of base intensity data containing reference intensity that provides a reference for intensity of reflected light from the workpiece, dark level data containing background intensity measured under a condition that light is cut off, and light monitoring data containing intensity of light of a light source for irradiating the workpiece.

In an embodiment, there is provided an abnormality detection method for preset spectrum data used for optically measuring a film thickness of a workpiece, comprising: determining reference spectrum data which is one of a plurality of preset spectra data acquired in the past; creating a latest preset spectrum data before polishing of the workpiece; calculating a difference between the reference spectrum data and the latest preset spectrum data; and determining that there is an abnormality in the latest preset spectrum data when the difference is larger than a threshold value.

In an embodiment, the difference is a Euclidean distance.

In an embodiment, determining the reference spectrum data includes: classifying the plurality of preset spectra data acquired in the past into groups according to algorithm of clustering; and determining the reference spectrum data which is one selected from a plurality of normal preset spectra data belonging to one of the groups.

In an embodiment, the abnormality detection method further comprises: normalizing the plurality of preset spectra data acquired in the past to create a plurality of normalized preset spectra data; and normalizing the latest preset spectrum data to create a latest normalized preset spectrum data.

In an embodiment, each of the plurality of preset spectra data acquired in the past and the latest preset spectrum data is one of base intensity data containing reference intensity that provides a reference for intensity of reflected light from the workpiece, dark level data containing background intensity measured under a condition that light is cut off, and light monitoring data containing intensity of light of a light source for irradiating the workpiece.

In an embodiment, there is provided an optical film-thickness measuring apparatus for optically measuring a film thickness of a workpiece, comprising: a light source configured to emit light; an optical sensor head configured to irradiate the workpiece with the light emitted by the light source and receive reflected light from the workpiece; and a processing system configured to determine the film thickness of the workpiece based on spectrum measurement data of the reflected light from the workpiece and preset spectrum data, the processing system being configured to: input the preset spectrum data to an autoencoder which is a trained model constructed by machine learning using training data including a plurality of normal preset spectra data; calculate a difference between output data output from the autoencoder and the preset spectrum data; and determine that there is an abnormality in the preset spectrum data when the difference is larger than a threshold value.

In an embodiment, the processing system is configured to: classify a plurality of preset spectra data acquired in the past into groups according to algorithm of clustering; produce the training data including a plurality of normal preset spectra data belonging to one of the groups; and perform the machine learning using the training data to construct the autoencoder which is the trained model.

In an embodiment, the preset spectrum data is one of base intensity data containing reference intensity that provides a reference for intensity of reflected light from the workpiece, dark level data containing background intensity measured under a condition that light is cut off, and light monitoring data containing intensity of light of the light source for irradiating the workpiece.

In an embodiment, there is provided an optical film-thickness measuring apparatus for optically measuring a film thickness of a workpiece, comprising: a light source configured to emit light; an optical sensor head configured to irradiate the workpiece with the light emitted by the light source and receive reflected light from the workpiece; and a processing system configured to determine the film thickness of the workpiece based on spectrum measurement data of the reflected light from the workpiece and preset spectrum data, the processing system being configured to: determine reference spectrum data which is one of a plurality of preset spectra data acquired in the past; create a latest preset spectrum data before polishing of the workpiece; calculate a difference between the reference spectrum data and the latest preset spectrum data; and determine that there is an abnormality in the latest preset spectrum data when the difference is larger than a threshold value.

In an embodiment, the difference is a Euclidean distance.

In an embodiment, the processing system is configured to: classify the plurality of preset spectra data acquired in the past into groups according to algorithm of clustering; and determine the reference spectrum data which is one selected from a plurality of normal preset spectra data belonging to one of the groups.

In an embodiment, the processing system is configured to: normalize the plurality of preset spectra data acquired in the past to create a plurality of normalized preset spectra data; and normalize the latest preset spectrum data to create a latest normalized preset spectrum data.

In an embodiment, each of the plurality of preset spectra data acquired in the past and the latest preset spectrum data is one of base intensity data containing reference intensity that provides a reference for intensity of reflected light from the workpiece, dark level data containing background intensity measured under a condition that light is cut off, and light monitoring data containing intensity of light of the light source for irradiating the workpiece.

The autoencoder is a trained model constructed by the machine learning using the training data including a plurality of normal preset spectra data. More specifically, the machine learning is performed such that, when preset spectrum data is input to the autoencoder, the autoencoder outputs substantially the same data as the input preset spectrum data. When abnormal preset spectrum data is input to the autoencoder, the autoencoder outputs data that is significantly different from the input preset spectrum data. Therefore, when the difference between the input preset spectrum data and the output data (which may be referred to as reconstruction error) is larger than a threshold value, it can be determined that the input preset spectrum data has an abnormality.

Similarly, when the difference between predetermined reference spectrum data and the latest preset spectrum data is larger than a threshold value, it can be determined that there is an abnormality in the latest preset spectrum data.

### BRIEF DESCRIPTION OF THE DRAWINGS

FIG. 1 is a schematic view showing an embodiment of a polishing apparatus;

FIG. 2 is a cross-sectional view showing an embodiment of a detailed configuration of an optical film-thickness measuring apparatus;

FIG. 3 is a graph showing an example of spectrum measurement data;

FIG. 4 shows a spectrum representing an example of base intensity data;

FIG. 5 shows a spectrum representing an example of dark level data;

FIG. 6 shows a spectrum representing an example of relative reflectance data;

FIG. 7 is a schematic diagram showing an example of an autoencoder;

FIG. 8 is a diagram showing an example when base intensity data as normal preset spectrum data is input to the autoencoder;

FIG. 9 is a diagram showing an example when base intensity data as abnormal preset spectrum data is input to the autoencoder;

FIG. 10 is a graph showing an example of results of periodically determining whether or not there is an abnormality in base intensity data using the autoencoder;

FIG. 11 is a flowchart illustrating an embodiment of detecting abnormality in preset spectrum data;

FIG. 12 is a diagram showing an example in which a plurality of preset spectra data are divided into three groups by clustering;

FIG. 13 is a schematic diagram of a polishing apparatus including another embodiment of an optical film-thickness measuring apparatus;

FIG. 14 is a flowchart illustrating another embodiment of detecting abnormality in preset spectrum data;

FIG. 15A is a graph showing an example of a plurality of preset spectra data before being normalized;

FIG. 15B is a graph showing an example of a plurality of preset spectra data after being normalized;

FIG. 16A is a graph showing results of periodically calculating a difference between the reference spectrum data before being normalized and latest preset spectrum data; and

FIG. 16B is a graph showing results of periodically calculating a difference between the reference spectrum data after being normalized and latest preset spectrum data.

### DESCRIPTION OF EMBODIMENTS

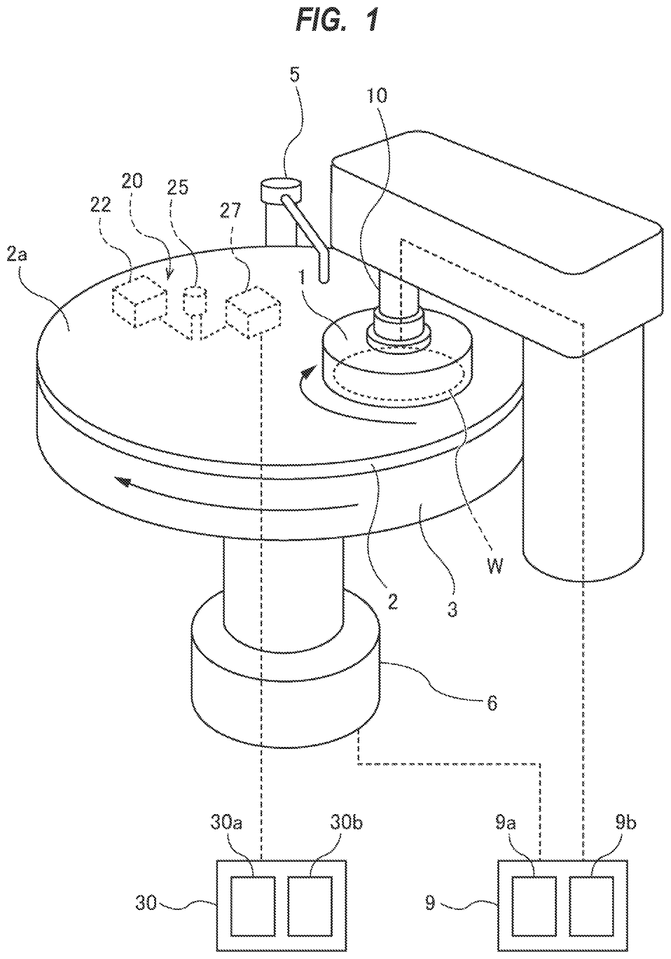

Hereinafter, embodiments will be described with reference to the drawings. FIG. 1 is a schematic view showing an embodiment of a polishing apparatus. As shown in FIG. 1, the polishing apparatus includes a polishing table 3 that supports a polishing pad 2, a polishing head 1 configured to press a workpiece W having a film against the polishing pad 2, a table motor 6 configured to rotate the polishing table 3, a polishing-liquid supply nozzle 5 configured to supply a polishing liquid, such as slurry, onto the polishing pad 2, and an operation controller 9 configured to control operations of the polishing apparatus. The polishing pad 2 has an upper surface that constitutes a polishing surface 2a for polishing the workpiece W. Examples of the workpiece W include a wafer, a substrate (e.g., a circular substrate, a polygonal substrate), and a panel which are used in manufacturing of semiconductor devices.

The polishing head 1 is coupled to a head shaft 10, which is coupled to a polishing-head motor (now shown). The polishing head motor is configured to rotate the polishing head 1 together with the head shaft 10 in a direction indicated by an arrow. The polishing table 3 is coupled to the table motor 6, which is configured to rotate the polishing table 3 and the polishing pad 2 in a direction indicated by an arrow. The polishing head 1, the polishing head motor, the polishing-liquid supply nozzle 5, and the table motor 6 are coupled to the operation controller 9.

Polishing of the workpiece W is performed as follows. The polishing-liquid supply nozzle 5 supplies the polishing liquid onto the polishing surface 2a of the polishing pad 2 on the polishing table 3, while the polishing table 3 and the polishing head 1 are rotated in the directions indicated by the arrows in FIG. 1. While the workpiece W is being rotated by the polishing head 1, the workpiece W is pressed by the polishing head 1 against the polishing surface 2a of the polishing pad 2 in the presence of the polishing liquid on the polishing pad 2. The surface of the workpiece W is polished by a chemical action of the polishing liquid and a mechanical action of abrasive grains contained in the polishing liquid and the polishing pad 2.

The operation controller 9 includes a memory 9a storing programs therein, and a processor 9b configured to execute arithmetic operations according to instructions included in the programs. The operation controller 9 is composed of at least one computer. The memory 9a includes a main memory, such as a random access memory (RAM), and an auxiliary memory, such as a hard disk drive (HDD) or solid state drive (SSD). Examples of the processor 9b include a CPU (central processing unit) and a GPU (graphic processing unit). However, the specific configurations of the operation controller 9 are not limited to these examples.

The polishing apparatus includes an optical film-thickness measuring apparatus 20 configured to measure a thickness of the film of the workpiece W. The optical film-thickness measuring apparatus 20 includes a light source 22 configured to emit light, an optical sensor head 25 configured to irradiate the workpiece W with the light from the light source 22 and receive reflected light from the workpiece W, a spectrometer 27 coupled to the optical sensor head 25, and a processing system 30 configured to determine the thickness of the film of the workpiece W based on the reflected light from the workpiece W. The optical sensor head 25 is arranged in the polishing table 3 and rotates together with the polishing table 3. Although not shown, optical sensor heads 25 each coupled to the spectrometer 27 and the light source 22 may be provided.

The processing system 30 includes a memory 30a storing programs therein, and an arithmetic device 30b configured to execute arithmetic operations according to instructions included in the programs. The processing system 30 is composed of at least one computer. The memory 30a includes a main memory, such as a random access memory (RAM), and an auxiliary memory, such as a hard disk drive (HDD) or solid state drive (SSD). Examples of the arithmetic device 30b include a CPU (central processing unit) and a GPU (graphic processing unit). However, the specific configurations of the processing system 30 are not limited to these examples.

Each of the operation controller 9 and the processing system 30 may be comprised of computers. For example, each of the operation controller 9 and the processing system 30 may be a combination of edge server and cloud server. In one embodiment, the operation controller 9 and the processing system 30 may be constituted of a single computer.

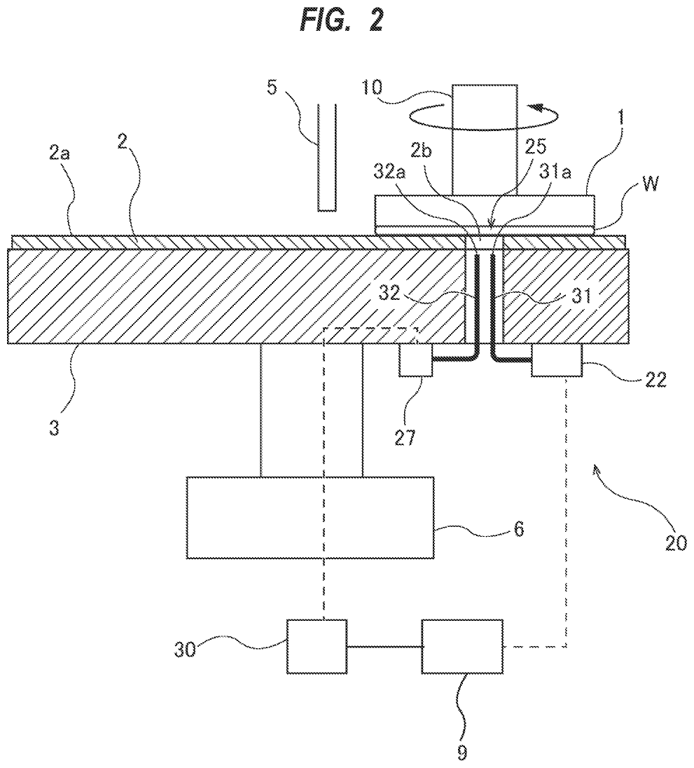

FIG. 2 is a cross-sectional view showing a detailed configuration of the optical film-thickness measuring apparatus 20. The optical film-thickness measuring apparatus 20 includes a light-emitting optical fiber cable 31 coupled to the light source 22 and a light-receiving optical fiber cable 32 coupled to the spectrometer 27. A distal end 31a of the light-emitting optical fiber cable 31 and a distal end 32a of the light-receiving optical fiber cable 32 constitute the optical sensor head 25. Specifically, the light-emitting optical fiber cable 31 directs the light, emitted by the light source 22, to the workpiece W on the polishing pad 2, and the light-receiving optical fiber cable 32 receives the reflected light from the workpiece W and transmits the reflected light to the spectrometer 27.

The spectrometer 27 is coupled to the processing system 30. The light-emitting optical fiber cable 31, the light-receiving optical fiber cable 32, the light source 22, and the spectrometer 27 are mounted to the polishing table 3 and rotate together with the polishing table 3 and the polishing pad 2. The optical sensor head 25, composed of the distal end 31a of the light-emitting optical fiber cable 31 and the distal end 32a of the light-receiving optical fiber cable 32, is arranged so as to face the surface of the workpiece W on the polishing pad 2. The position of the optical sensor head 25 is such that the optical sensor head 25 traverses the surface of the workpiece W on the polishing pad 2 each time the polishing table 3 and polishing pad 2 make one rotation. The polishing pad 2 has a through-hole 2b located above the optical sensor head 25. The optical sensor head 25 irradiates the workpiece W with the light through the through-hole 2b and receives the reflected light from the workpiece W through the through-hole 2b each time the polishing table 3 makes one rotation.

The light source 22 may be a flash light source configured to repeatedly emit light at short time intervals. Examples of the light source 22 include xenon flash lamp. The light source 22 is electrically coupled to the operation controller 9 and emits the light upon receiving a trigger signal sent from the operation controller 9. More specifically, while the optical sensor head 25 sweeps across the surface of the workpiece W on the polishing pad 2, the light source 22 receives a plurality of trigger signals and emits the light multiple times. Therefore, multiple measurement points on the workpiece W are irradiated with the light each time the polishing table 3 makes one rotation.

The light emitted by the light source 22 is transmitted through the light-emitting optical fiber cable 31 to the optical sensor head 25 and emitted from the optical sensor head 25. The light is incident on the workpiece W on the polishing pad 2 through the through-hole 2b of the polishing pad 2. The reflected light from the workpiece W passes through the through-hole 2b of the polishing pad 2 again and is received by the optical sensor head 25. The reflected light from the workpiece W is transmitted through light-receiving optical fiber cable 32 to the spectrometer 27.

The spectrometer 27 is configured to decompose the reflected light according to wavelengths and to measure intensity of the reflected light at each of the wavelengths over a predetermined wavelength range. Specifically, the spectrometer 27 decomposes the reflected light from the workpiece W according to wavelengths and measures the intensity of the reflected light at each of the wavelengths over the predetermined wavelength range to thereby generate spectrum measurement data. The spectrum measurement data is sent to the processing system 30.

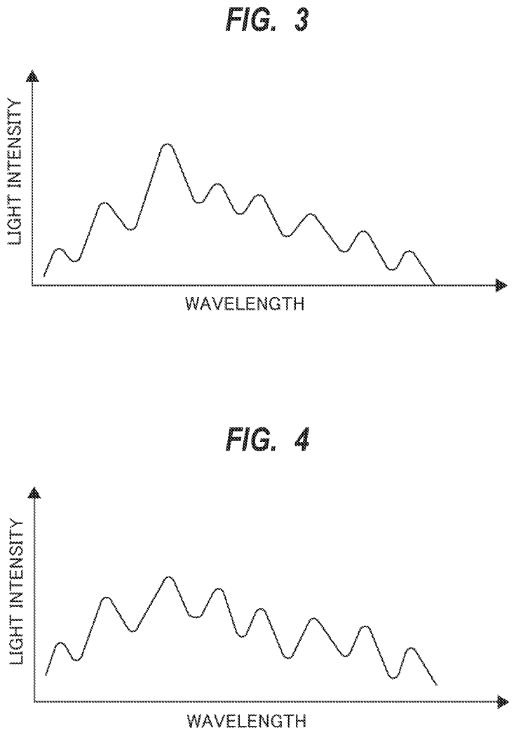

FIG. 3 is a graph showing an example of the spectrum measurement data. In FIG. 3, vertical axis represents the intensity of the reflected light from the workpiece W, and horizontal axis represents the wavelength of the reflected light. As shown in FIG. 3, the spectrum measurement data can be expressed as a spectrum (spectral waveform) indicating a relationship between the wavelength and intensity of the light.

The processing system 30 is configured to determine the film thickness of the workpiece W based on the spectrum measurement data of the reflected light from the workpiece W and preset spectrum data described below. More specifically, the processing system 30 generates relative reflectance data from the spectrum measurement data and the preset spectrum data, and determines the film thickness of the workpiece W based on the relative reflectance data. The relative reflectance data includes a plurality of relative reflectances calculated at a plurality of wavelengths. The relative reflectance is an index value that represents the intensity of the reflected light. The relative reflectance is a ratio of the intensity of the light to a predetermined reference intensity. The intensity of the light (i.e., an actually measured intensity) at each of the wavelengths is divided by a predetermined reference intensity, so that unwanted noises, such as a variation in the intensity inherent in an optical system or the light source of the apparatus, can be removed from the actually measured intensity.

The processing system 30 stores the following calculation formula (1) for calculating relative reflectance data R(λ) in the memory 30a. The relative reflectance data R(λ) is calculated using the following calculation formula (1)

$$R ( λ ) = \frac{E ( λ ) - D ( λ )}{B ( λ ) - D ( λ )} \qquad ( 1 )$$

where λ is the wavelength, E(λ) is the spectrum measurement data representing the intensity at the wavelength λ of the light reflected from the workpiece W, B(λ) is base intensity data representing the reference intensity at the wavelength λ, and D(λ) is dark level data representing a background intensity (dark level) at the wavelength λ that has been measured under a condition that light is cut off. The wavelength λ is a wavelength within a predetermined wavelength range. The preset spectrum data used to determine the film thickness of the workpiece W includes at least the base intensity data B(λ) and the dark level data D(λ) contained in the above calculation formula (1).

The base intensity data B(λ) is data of the reference intensity of light measured over the predetermined wavelength range. For example, the base intensity data B(λ) can be obtained by directly measuring the intensity of light emitted from the optical sensor head 25 over a predetermined wavelength range, or by irradiating a mirror with the light from the optical sensor head 25 and measuring the intensity of reflected light from the mirror over a predetermined wavelength range using the spectrometer 27. Alternatively, the base intensity data B(λ) may be obtained by measuring intensity of reflected light from a silicon wafer (or a bare wafer) having no film thereon with the spectrometer 27 over a predetermined wavelength range when the silicon wafer (or the bare wafer) is water-polished in the presence of water on the polishing pad 2 or when the silicon wafer (or the bare wafer) is placed on the polishing pad 2.

The dark level data D(λ) is data of the background intensity (dark level) measured by the spectrometer 27 over the above-mentioned predetermined wavelength range under the condition that light is cut off. The light-cut-off environment for measuring the dark level data D(λ) can be produced by cutting off the light with a shutter (not shown) installed in the spectrometer 27.

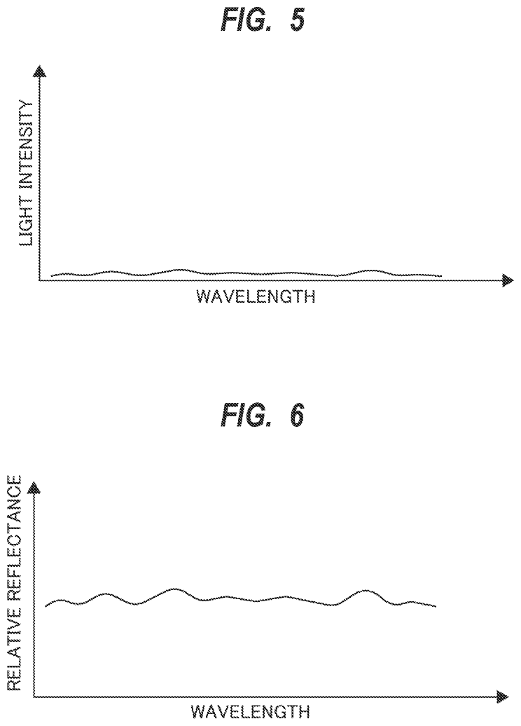

Each of the base intensity data B(λ) and the dark level data D(λ) can be expressed as a spectrum indicating a relationship between light intensity and wavelength. FIG. 4 shows a spectrum representing an example of the base intensity data B(λ), and FIG. 5 shows a spectrum representing an example of the dark level data D(λ). Furthermore, FIG. 6 shows a spectrum representing an example of the relative reflectance data R(λ).

The spectrum measurement data E(λ) is generated during polishing of the workpiece W. The base intensity data B(λ) and the dark level data D(λ) are generated before the workpiece W is polished. For example, the base intensity data B(λ) and the dark level data D(λ) are generated when the polishing apparatus is in an idling state or immediately after the polishing pad is replaced with a new polishing pad.

As can be seen from the above equation (1), the relative reflectance is calculated at each of the wavelengths. Specifically, the dark level is subtracted from the measured intensity of light at each wavelength to determine a corrected measured intensity, the dark level is further subtracted from the corresponding reference intensity to determine a corrected reference intensity, and the corrected measured intensity is divided by the corrected reference intensity, so that the relative reflectance is determined.

The processing system 30 uses the calculation formula (1) to calculate the relative reflectance data R(λ) from the spectrum measurement data E(λ) which is actually measured data of the intensity of reflected light from the workpiece W, and the base intensity data B(λ) and the dark level data D(λ) that have been prepared in advance. The processing system 30 determines the film thickness of the workpiece W based on the relative reflectance data R(λ).

A known technique is used to determine the film thickness of the workpiece W based on the relative reflectance data R(λ). For example, the processing system 30 determines from a reference spectra library a reference spectrum having a shape that is closest to the spectrum of the relative reflectance data R(λ), and determines the film thickness associated with the determined reference spectrum. In another example, the processing system 30 performs a Fourier transform on the spectrum of the relative reflectance data R(λ) and determines the film thickness from a resulting frequency spectrum.

The processing system 30 has a function of automatically detecting whether or not there are abnormalities in the base intensity data B (λ) and the dark level data D (λ) which are the preset spectrum data. The abnormality in the base intensity data B (λ) and the dark level data D (λ) may be caused by a malfunction of the optical film-thickness measuring apparatus 20, such as a malfunction of the light source 22, a malfunction of the light-emitting optical fiber cable 31, or a malfunction of the light-receiving optical fiber cable 32. If there are abnormalities in the base intensity data B(λ) and the dark level data D(λ), the processing system 30 cannot determine an accurate film thickness of the workpiece W.

Therefore, in this embodiment, the processing system 30 is configured to periodically detect whether or not there are abnormalities in the base intensity data B (λ) and the dark level data D (λ) which are the preset spectrum data. More specifically, the processing system 30 inputs the preset spectrum data (the base intensity data B (λ) or the dark level data D (λ)) to an autoencoder, and calculates a difference between the preset spectrum data and the output data output from the autoencoder.

The autoencoder is a trained model constructed by machine learning using training data including a plurality of normal preset spectra data. More specifically, the machine learning is performed such that, when the preset spectrum data is input to the autoencoder, the autoencoder outputs substantially the same data as the input preset spectrum data. When abnormal preset spectrum data is input to the autoencoder, the autoencoder outputs data that is significantly different from the input preset spectrum data.

The processing system 30 is configured to determine that there is an abnormality in the input preset spectrum data when the difference (which may be referred to as reconstruction error) between the input preset spectrum data and the output data is larger than a threshold value.

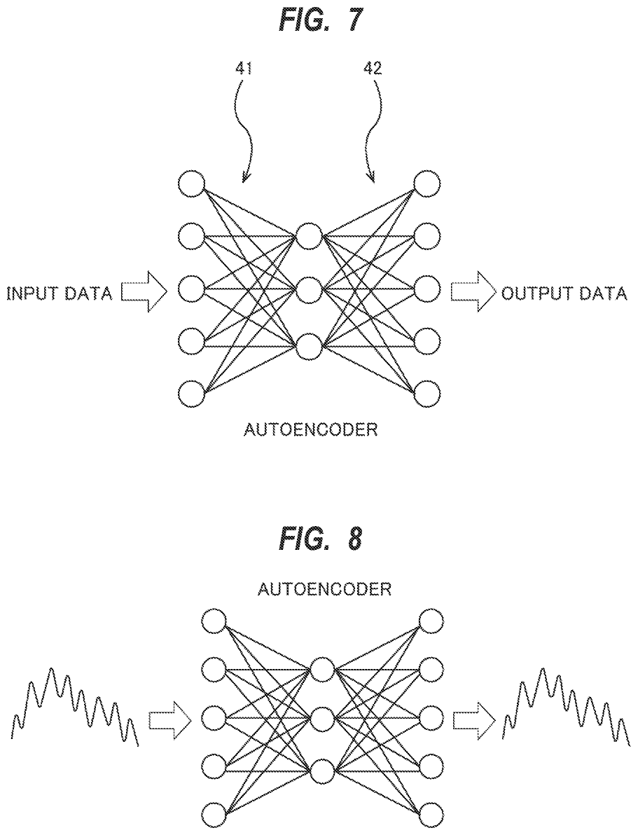

FIG. 7 is a schematic diagram showing an example of the autoencoder. The autoencoder includes an encoder 41 that extracts features of the input preset spectrum data, and a decoder 42 that reconstructs the input preset spectrum data from the extracted features.

FIG. 8 is a diagram showing an example when the base intensity data B(λ) as normal preset spectrum data is input to the autoencoder. The autoencoder is the trained model constructed by the machine learning using the training data including a plurality of normal preset spectra data. Therefore, as shown in FIG. 8, when normal base intensity data B(λ) is input to the autoencoder, the autoencoder outputs the output data that is substantially the same as the input base intensity data B(λ). Therefore, the difference (reconstruction error) between the input base intensity data B(λ) and the output data is small.

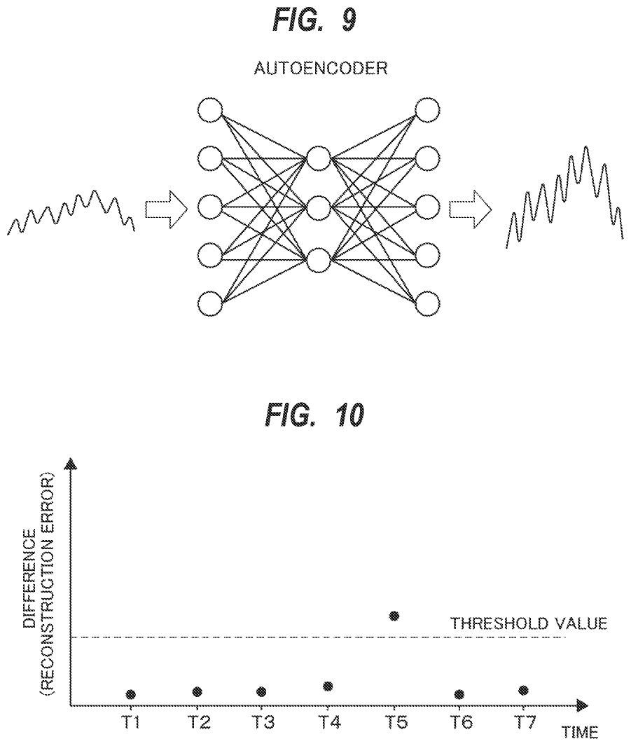

FIG. 9 is a diagram showing an example when the base intensity data B(λ) as abnormal preset spectrum data is input to the autoencoder. As shown in FIG. 9, when abnormal base intensity data B(λ) is input to the autoencoder, the autoencoder outputs the output data that is significantly different from the input base intensity data B(λ). Therefore, the difference (reconstruction error) between the input base intensity data B(λ) and the output data is large.

FIG. 10 is a graph showing an example of results of periodically determining whether or not there is an abnormality in the base intensity data B(A) using the autoencoder. In FIG. 10, vertical axis represents the difference (reconstruction error) between the input base intensity data B(λ) and the output data, and horizontal axis represents time. At times T1 to T4 and T6 to T7, the difference is smaller than the threshold value, while at time T5, the difference is larger than the threshold value. When the difference between the input base intensity data B(λ) and the output data is larger than the threshold value, the processing system 30 determines that there is an abnormality in the input base intensity data B(λ).

Similarly, the processing system 30 can determine whether or not there is an abnormality in the dark level data D(λ) using the autoencoder. In order to ensure accurate measuring of a film thickness of a workpiece, the processing system 30 is configured to determine whether or not there are abnormalities in the base intensity data B(λ) and the dark level data D(λ) using the autoencoder.

Autoencoders may be provided for the base intensity data B (λ) and the dark level data D (λ), respectively, or a common autoencoder may be provided for the base intensity data B (λ) and the dark level data D (λ).

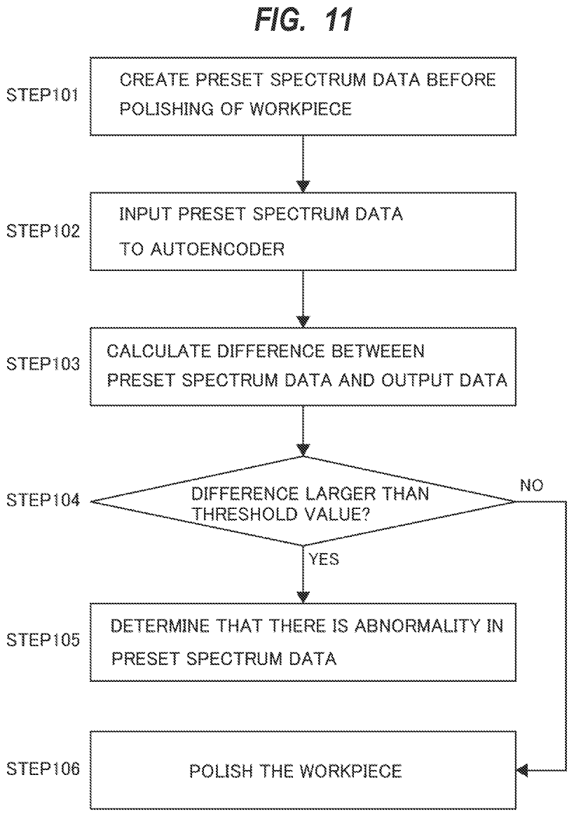

FIG. 11 is a flowchart illustrating an embodiment of detecting an abnormality in the preset spectrum data.

In step 101, the spectrometer 27 creates the preset spectrum data before polishing of the workpiece W. The preset spectrum data is the base intensity data B(λ) or the dark level data D(λ).

In step 102, the processing system 30 inputs the preset spectrum data to the autoencoder which is a trained model.

In step 103, the processing system 30 calculates the difference between the preset spectrum data input to the autoencoder and the output data output from the autoencoder.

In step 104, the processing system 30 determines whether the difference is greater than the threshold value.

In step 105, the processing system 30 determines that there is an abnormality in the preset spectrum data when the difference is larger than the threshold value.

In step 106, if the difference is smaller than the threshold value, the workpiece W is polished.

The training data used for the machine learning of the autoencoder includes normal preset spectrum data among a large number of preset spectrum data obtained from past polishing, experiments, etc. The normal preset spectrum data is data that has been acquired when the optical film-thickness measuring apparatus 20 works properly (i.e., when there is no malfunction in the light source 22, the optical fiber cables 31, 32, etc.). The huge number of preset spectrum data acquired in the past may include abnormal preset spectrum data (i.e., preset spectrum data acquired when the optical film-thickness measuring apparatus 20 involves a malfunction).

Therefore, in one embodiment, the processing system 30 is configured to classify a plurality of preset spectra data acquired in the past into multiple groups according to an algorithm of clustering, and create the training data including a plurality of normal preset spectra data belonging to one of the multiple groups. The processing system 30 is further configured to perform the machine learning using the training data to construct the autoencoder that is a trained model.

The clustering is called cluster analysis, and the clustering algorithm is a type of artificial intelligence algorithm that classifies the plurality of preset spectra data based on their features. The memory 30a of the processing system 30 stores a program for classifying a plurality of preset spectra data into groups according to the algorithm of the clustering. The arithmetic device 30b of the processing system 30 classifies the plurality of preset spectra data into the groups by performing arithmetic operations according to instructions included in the program.

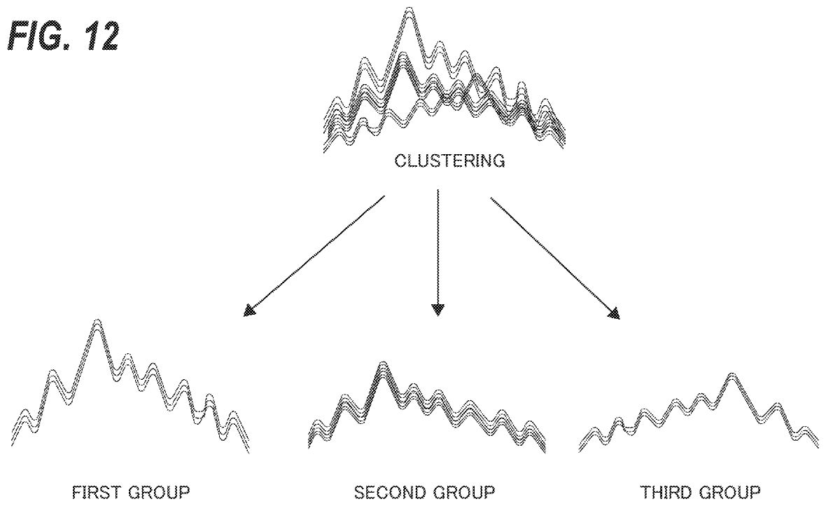

FIG. 12 is a diagram showing an example of classifying a plurality of preset spectra data into three groups by the clustering. In the example shown in FIG. 12, the processing system 30 performs the machine learning using, as training data, preset spectrum data included in a second group which is a group of normal preset spectrum data. The clustering can quickly classify a huge number of previously acquired preset spectrum data into normal preset spectrum data and abnormal preset spectrum data. In the example shown in FIG. 12, the plurality of preset spectra data are divided into the three groups, while they may be divided into two groups or four or more groups.

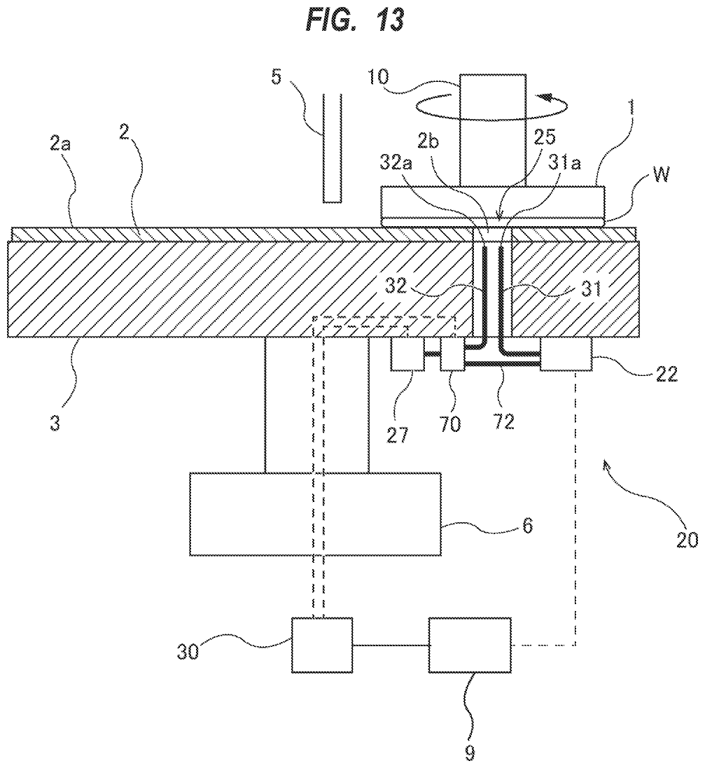

Next, another embodiment of the optical film-thickness measuring apparatus 20 will be described with reference to FIG. 13. FIG. 13 is a schematic diagram of a polishing apparatus including another embodiment of the optical film-thickness measuring apparatus 20. Configurations and operations of this embodiment, which are not particularly described, are the same as those of the above embodiments described with reference to FIGS. 1 to 12, and therefore, redundant explanations thereof will be omitted.

In this embodiment, the preset spectrum data includes light monitoring data described below in addition to the base intensity data and the dark level data described above. The light monitoring data is data for monitoring a decrease in a quantity of light of the light source 22 over time. The light monitoring data is used to measure the film thickness of the workpiece W, as well as the base intensity data and the dark level data.

The optical film-thickness measuring apparatus 20 of the present embodiment includes a bypass optical fiber cable 72 configured to directly transmit the light emitted by the light source 22 to the spectrometer 27 by bypassing the light-emitting optical fiber cable 31 and the light-receiving optical fiber cable 32. The optical film-thickness measuring apparatus 20 of the present embodiment further includes an optical path selecting device 70 configured to selectively couple the spectrometer 27 to either the light-receiving optical fiber cable 32 or the bypass optical fiber cable 72. The light-receiving optical fiber cable 32 is coupled to the optical path selecting device 70. One end of the bypass optical fiber cable 72 is coupled to the light source 22, and the other end of the bypass optical fiber cable 72 is coupled to the optical path selecting device 70. The optical path selecting device 70 is optically coupled to the spectrometer 27.

When the optical path selecting device 70 optically couples the light-receiving optical fiber cable 32 to the spectrometer 27, the reflected light from the workpiece W is transmitted to the spectrometer 27 through the light-receiving optical fiber cable 32 and the optical path selecting device 70. When the optical path selecting device 70 optically couples the bypass optical fiber cable 72 to the spectrometer 27, the light emitted by the light source 22 is transmitted to the spectrometer 27 through the bypass optical fiber cable 72 and the optical path selecting device 70 without passing through the light-emitting optical fiber cable 31 and the light-receiving optical fiber cable 32. The operation of optical path selecting device 70 is controlled by the processing system 30. Examples of the optical path selecting device 70 include an optical switch and an optical shutter.

As described above, the optical film-thickness measuring apparatus 20 directs the light, emitted by the light source 22, to the workpiece W, and determines the film thickness of the workpiece W by analyzing the reflected light from the workpiece W. However, a quantity of light emitted by the light source 22 is gradually lowered with an operating time of the light source 22. As a result, an error between a true film thickness and a measured film thickness becomes larger. Thus, in this embodiment, the optical film-thickness measuring apparatus 20 is configured to correct the intensity of the reflected light from the workpiece W based on the intensity of light transmitted to the spectrometer 27 through the bypass optical fiber cable 72, and compensate for the decrease in the quantity of light of the light source 22.

The processing system 30 calculates a corrected intensity of the reflected light with use of the following calculation formula (2), instead of the aforementioned formula (1).

$${R}^{′} ( λ ) = [ E ( λ ) - D 3 ( λ ) ] / [ [ B ( λ ) - D 1 ( λ ) ] \times \frac{G ( λ ) - D 3 ( λ )}{F ( λ ) - D 2 ( λ )} ] \qquad ( 2 )$$

where, E(λ) is spectrum measurement data representing intensity at wavelength λ of the reflected light from the workpiece W, B(λ) is base intensity data representing reference intensity at the wavelength λ, D1(λ) is dark level data representing background intensity (dark level) at the wavelength λ measured under a condition that light is cut off immediately before or immediately after the base intensity data B(λ) is measured, F(λ) is light monitoring data representing intensity at the wavelength λ of the light of the light source 22 transmitted to the spectrometer 27 through the bypass optical fiber cable 72 immediately before or immediately after the base intensity data B(λ) is measured, D2 (λ) is dark level data representing background intensity (dark level) at the wavelength λ measured under a condition that light is cut off immediately before or immediately after the light monitoring data F(λ) is measured, G(λ) is light monitoring data representing intensity at the wavelength λ of the light of the light source 22 transmitted to the spectrometer 27 through the bypass optical fiber cable 72 before the spectrum measurement data E(λ) is measured, and D3(λ) is dark level data representing background intensity (dark level) at the wavelength λ measured under a condition that light is cut off before the spectrum measurement data E(λ) is measured and immediately before or immediately after the light monitoring data G(λ) is measured.

The wavelength λ is a wavelength within a predetermined wavelength range. E(A), B(λ), D1(λ), F(λ), D2(λ), G(λ), and D3(λ) are data measured over the above-mentioned predetermined wavelength range. The dark level data D1(λ), D2(λ), and D3(λ) are measured in the same manner as the dark level data D(λ) in the embodiment discussed previously. The light-cut-off environment for measuring the dark level data D1(λ), D2(λ), and D3(λ) can be produced by cutting off the light with a shutter (not shown) installed in the spectrometer 27.

The processing system 30 stores, in the memory 30a, the calculation formula (2) in advance. The base intensity data B(λ), the dark level data D1(λ), the light monitoring data F(λ), and the dark level data D2(λ) are measured in advance before polishing of the workpiece W, and are input as constants to the above calculation formula (2) in advance. The spectrum measurement data E(λ) is measured during polishing of the workpiece W. The light monitoring data G(λ) and the dark level data D3(λ) are measured before polishing of the workpiece W (preferably immediately before polishing of the workpiece W).

The light monitoring data F(λ), G(λ) are measured before the workpiece W is polished. Specifically, the processing system 30 operates the optical path selecting device 70 to couple the bypass optical fiber cable 72 to the spectrometer 27 so that the light of the light source 22 is transmitted through the bypass optical fiber cable 72 to the spectrometer 27. The spectrometer 27 measures the intensity of the light of the light source 22 over the predetermined wavelength range and creates the light monitoring data F(λ) and G(λ). The spectrometer 27 sends the light monitoring data F(λ), G(λ) to the processing system 30.

The processing system 30 inputs the light monitoring data and the dark level data into the above calculation formula (2). The processing system 30 operates the optical path selecting device 70 to couple the light-receiving optical fiber cable 32 to the spectrometer 27. Thereafter, the workpiece W is polished, and the spectrum measurement data E(λ) is measured by the spectrometer 27 while the workpiece W is being polished.

During polishing of the workpiece W, the processing system 30 inputs measured values of the spectrum measurement data E(λ) into the calculation formula (2), and calculates the relative reflectance data R′(λ). More specifically, the processing system 30 calculates the relative reflectance over the predetermined wavelength range. The processing system 30 determines a film thickness of the workpiece W based on the relative reflectance data R′(λ). Since the relative reflectance data R′(λ) is created based on the corrected light intensity, the processing system 30 can determine an accurate film thickness of the workpiece W.

According to this embodiment, the reflected light from the workpiece W is corrected based on the light monitoring data G(λ) of the light of the light source 22 transmitted to the spectrometer 27 through the bypass optical fiber cable 72 before polishing of the workpiece W. Therefore, the processing system 30 can determine the accurate film thickness of the workpiece W.

The light monitoring data G(λ) and the dark level data D3(λ) may be measured each time a workpiece is polished, or each time a predetermined number of workpieces (e.g., 25 workpieces) are polished.

The base intensity data B(λ), the dark level data D1(λ), the light monitoring data F(λ), the dark level data D2(λ), the light monitoring data G(λ), and the dark level data D3(λ) are the preset spectrum data measured before polishing of the workpiece W. The processing system 30 is configured to determine whether or not there are abnormalities in the base intensity data B(λ), the dark level data D1(λ), the light monitoring data F(λ), the dark level data D2(λ), the light monitoring data G(λ), and the dark level data D3(λ) using the autoencoder in the same manner as in the embodiments previously discussed with reference to FIGS. 7 to 10.

Autoencoders may be provided for the base intensity data B(λ), the dark level data D1(λ), the light monitoring data F(λ), the dark level data D2(λ), the light monitoring data G(λ), and the dark level data D3(λ), respectively, or a common autoencoder may be provided for the base intensity data B(λ), the dark level data D1(λ), the light monitoring data F(λ), the dark level data D2(λ), the light monitoring data G(λ), and the dark level data D3(λ).

The abnormality detection for the preset spectrum data in this embodiment is performed in the same manner as in the flowchart described with reference to FIG. 11, and the repetitive explanations will be omitted.

The creation of the training data using the clustering described with reference to FIG. 12 can be applied to this embodiment.

Next, another embodiment of a method of detecting an abnormality in preset spectrum data will be described. Configurations and operations of the optical film-thickness measuring apparatus 20 used in this embodiment are the same as those of the above embodiments described with reference to FIGS. 1 and 2 or the above embodiments described with reference to FIG. 13, and therefore, redundant explanations thereof will be omitted.

In this embodiment, the processing system 30 is configured to determine reference spectrum data that is one of a plurality of preset spectra data that have been acquired in the past, create latest preset spectrum data before polishing of the workpiece, calculate a difference between the reference spectrum data and the latest preset spectrum data, and determine that there is an abnormality in the latest preset spectrum data when the difference is larger than a threshold value.

The preset spectrum data includes the base intensity data B(λ) and the dark level data D(λ) in the embodiment described with reference to FIGS. 1 to 12, and further includes the base intensity data B(λ), the dark level data D1(λ), the light monitoring data F(λ), the dark level data D2(λ), the light monitoring data G(λ), and the dark level data D3(λ) in the embodiment described with reference to FIG. 13.

The plurality of preset spectra data obtained in the past and prepared for determining the reference spectrum data are a plurality of preset spectra data obtained in past polishing, experiments, etc. The reference spectrum data is normal preset spectrum data acquired when the optical film-thickness measuring apparatus 20 works properly (i.e., when there is no malfunction in the light source 22, the optical fiber cables 31, 32, etc.). The processing system 30 selects one normal preset spectrum data from the plurality of previously acquired preset spectrum data, and determines the reference spectrum data that is the selected normal preset spectrum data. The reference spectrum data is stored in the memory 30a.

The processing system 30 creates the latest preset spectrum data before polishing of the workpiece W. The latest preset spectrum data is created in the same manner as in the embodiment described above. For example, the base intensity data, which is data of the reference intensity of light, can be obtained by directly measuring the intensity of light emitted from the optical sensor head 25 over a predetermined wavelength range, or by irradiating a mirror with the light from the optical sensor head 25 and measuring intensity of the reflected light from the mirror over a predetermined wavelength range using the spectrometer 27. Alternatively, the base intensity data may be obtained by measuring intensity of reflected light from a silicon wafer (or a bare wafer) having no film thereon with the spectrometer 27 over a predetermined wavelength range when the silicon wafer (or the bare wafer) is water-polished in the presence of water on the polishing pad 2 or when the silicon wafer (or the bare wafer) is placed on the polishing pad 2. The dark level data and the light monitoring data can be produced in the same manner as in the above-described embodiments, and redundant explanations thereof will be omitted.

The processing system 30 calculates the difference between the reference spectrum data and the latest preset spectrum data (e.g., the latest base intensity data, the latest dark level data, or the latest light monitoring data). In this embodiment, the processing system 30 calculates a Euclidean distance as the difference between the reference spectrum data and the latest preset spectrum data.

When the difference between the predetermined reference spectrum data and the latest preset spectrum data is smaller than the threshold value, the processing system 30 can determine that the latest preset spectrum data is normal. On the other hand, when the difference between the predetermined reference spectrum data and the latest preset spectrum data is larger than the threshold value, the processing system 30 can determine that there is an abnormality in the latest preset spectrum data.

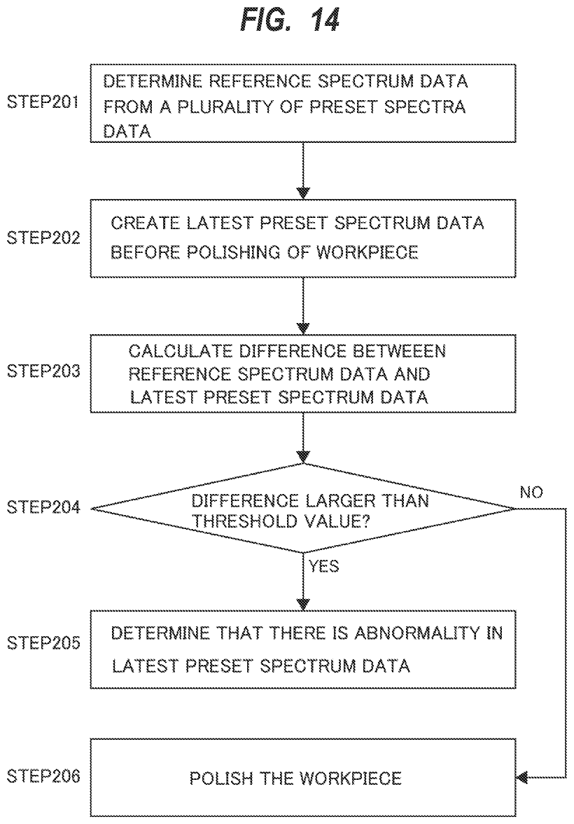

FIG. 14 is a flowchart illustrating one embodiment of detecting an abnormality in the preset spectrum data.

In step 201, the processing system 30 determines the reference spectrum data that is one of a plurality of previously acquired preset spectrum data. The reference spectrum data is the preset spectrum data that has been produced when the optical film-thickness measuring apparatus 20 has no malfunction.

In step 202, the spectrometer 27 produces the latest preset spectrum data before polishing of the workpiece W. The latest preset spectrum data is the latest base intensity data or the latest dark level data or the latest light monitoring data.

In step 203, the processing system 30 calculates the difference between the reference spectrum data and the latest preset spectrum data.

In step 204, the processing system 30 determines whether the difference is greater than a threshold value.

In step 205, the processing system 30 determines that there is an abnormality in the latest preset spectrum data when the difference is larger than the threshold value.

In step 206, if the difference is smaller than the threshold value, the workpiece W is polished.

The clustering described with reference to FIG. 12 can be applied to this embodiment. Specifically, the processing system 30 classifies a plurality of preset spectra data acquired in the past into multiple groups according to an algorithm of the clustering, selects one of a plurality of normal preset spectra data belonging to one of the multiple groups, and determines the reference spectrum data which is the selected normal preset spectrum data. The clustering can quickly divide a huge number of previously acquired preset spectrum data into normal preset spectrum data and abnormal preset spectrum data.

In one embodiment, the processing system 30 may be configured to normalize a plurality of preset spectra data acquired in the past to create a plurality of normalized preset spectra data, and select a reference spectrum from the plurality of normalized preset spectra data. The processing system 30 may be configured to normalize the latest preset spectrum data to create latest normalized preset spectrum data.

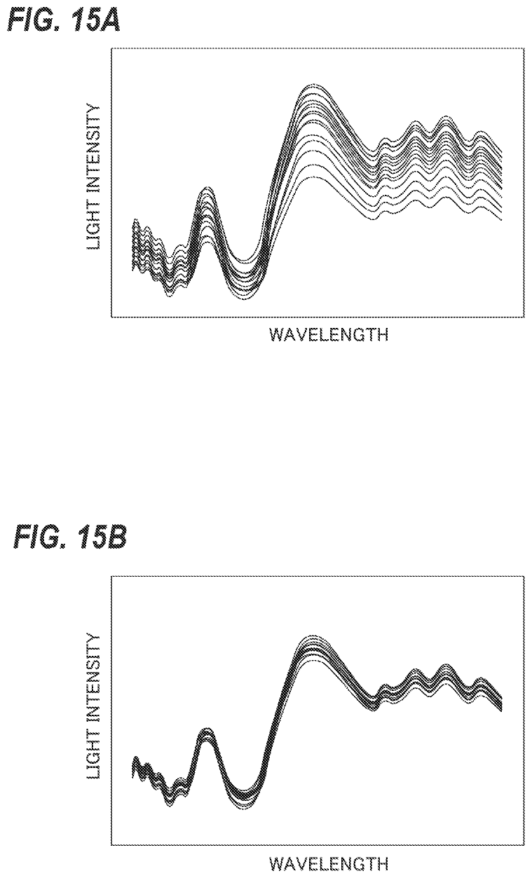

FIG. 15A is a graph showing an example of a plurality of preset spectra data before being normalized, and FIG. 15B is a graph showing an example of a plurality of preset spectra data after being normalized. As can be seen from the comparison between FIG. 15A and FIG. 15B, the normalization can reduce a variation in level of the preset spectrum data.

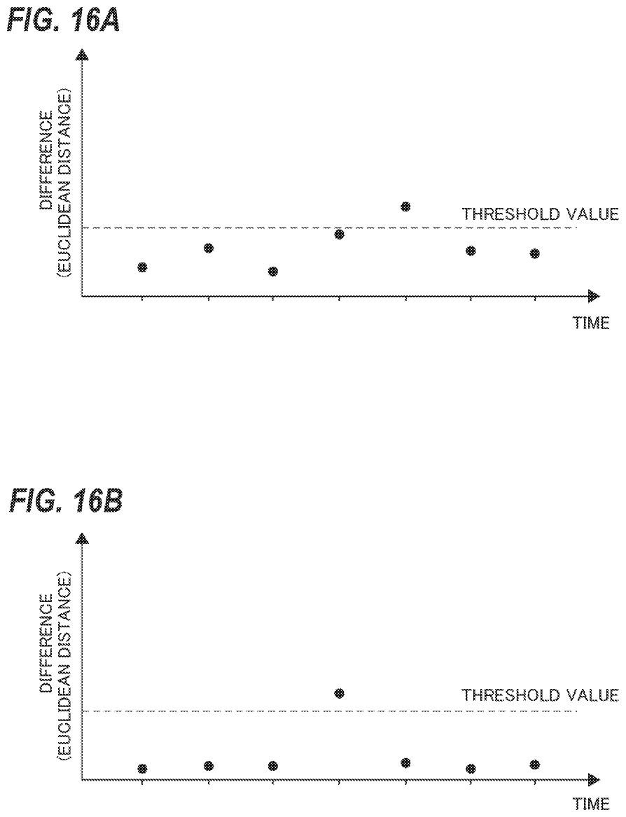

FIG. 16A is a graph showing results of periodically calculating the difference between the reference spectrum data before being normalized and the latest preset spectrum data, and FIG. 16B is a graph showing results of periodically calculating the difference between the reference spectrum data after being normalized and the latest preset spectrum data. In FIGS. 16A and 16B, vertical axis represents the difference (Euclidean distance) between the reference spectrum data and the latest preset spectrum data, and horizontal axis represents time.

As can be seen from the comparison between FIG. 16A and FIG. 16B, the normalization of the preset spectrum data can reduce a variation in the difference between the reference spectrum data and the latest preset spectrum data. As a result, the processing system 30 can correctly determine whether there is an abnormality in the latest preset spectrum data (e.g., the base intensity data, or the dark level data, or the light monitoring data) based on the comparison between the difference and the threshold value.

In the embodiments described so far, one optical sensor head 25 is provided, but the present invention is not limited to the above embodiments, and optical sensor heads 25 may be provided in the polishing table 3. For example, the optical sensor heads 25 may be arranged so as to pass across different regions of the workpiece W (for example, the center region and the edge region) as the polishing table 3 rotates.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. An abnormality detection method for preset spectrum data used for optically measuring a film thickness of a workpiece, comprising:
creating the preset spectrum data before polishing of the workpiece;
inputting the preset spectrum data to an autoencoder which is a trained model constructed by machine learning using training data including a plurality of normal preset spectra data;
calculating a difference between output data output from the autoencoder and the preset spectrum data; and
determining that there is an abnormality in the preset spectrum data when the difference is larger than a threshold value.

2. The abnormality detection method according to claim 1, further comprising:
classifying a plurality of preset spectra data acquired in the past into groups according to algorithm of clustering;
producing the training data including a plurality of normal preset spectra data belonging to one of the groups; and
performing the machine learning using the training data to construct the autoencoder which is the trained model.

3. The abnormality detection method according to claim 1, wherein the preset spectrum data is one of base intensity data containing reference intensity that provides a reference for intensity of reflected light from the workpiece, dark level data containing background intensity measured under a condition that light is cut off, and light monitoring data containing intensity of light of a light source for irradiating the workpiece.

4. An abnormality detection method for preset spectrum data used for optically measuring a film thickness of a workpiece, comprising:
determining reference spectrum data which is one of a plurality of preset spectra data acquired in the past;
creating a latest preset spectrum data before polishing of the workpiece;
calculating a difference between the reference spectrum data and the latest preset spectrum data; and
determining that there is an abnormality in the latest preset spectrum data when the difference is larger than a threshold value.

5. The abnormality detection method according to claim 4, wherein the difference is a Euclidean distance.

6. The abnormality detection method according to claim 4, wherein determining the reference spectrum data includes:
classifying the plurality of preset spectra data acquired in the past into groups according to algorithm of clustering; and
determining the reference spectrum data which is one selected from a plurality of normal preset spectra data belonging to one of the groups.

7. The abnormality detection method according to claim 4, further comprising:
normalizing the plurality of preset spectra data acquired in the past to create a plurality of normalized preset spectra data; and
normalizing the latest preset spectrum data to create a latest normalized preset spectrum data.

8. The abnormality detection method according to claim 4, wherein each of the plurality of preset spectra data acquired in the past and the latest preset spectrum data is one of base intensity data containing reference intensity that provides a reference for intensity of reflected light from the workpiece, dark level data containing background intensity measured under a condition that light is cut off, and light monitoring data containing intensity of light of a light source for irradiating the workpiece.

9. An optical film-thickness measuring apparatus for optically measuring a film thickness of a workpiece, comprising:
a light source configured to emit light;
an optical sensor head configured to irradiate the workpiece with the light emitted by the light source and receive reflected light from the workpiece; and
a processing system configured to determine the film thickness of the workpiece based on spectrum measurement data of the reflected light from the workpiece and preset spectrum data, the processing system being configured to:
input the preset spectrum data to an autoencoder which is a trained model constructed by machine learning using training data including a plurality of normal preset spectra data;
calculate a difference between output data output from the autoencoder and the preset spectrum data; and
determine that there is an abnormality in the preset spectrum data when the difference is larger than a threshold value.

10. The optical film-thickness measuring apparatus according to claim 9, wherein the processing system is configured to:
classify a plurality of preset spectra data acquired in the past into groups according to algorithm of clustering;
produce the training data including a plurality of normal preset spectra data belonging to one of the groups; and
perform the machine learning using the training data to construct the autoencoder which is the trained model.

11. The optical film-thickness measuring apparatus according to claim 9, wherein the preset spectrum data is one of base intensity data containing reference intensity that provides a reference for intensity of reflected light from the workpiece, dark level data containing background intensity measured under a condition that light is cut off, and light monitoring data containing intensity of light of the light source for irradiating the workpiece.

12. An optical film-thickness measuring apparatus for optically measuring a film thickness of a workpiece, comprising:
a light source configured to emit light;
an optical sensor head configured to irradiate the workpiece with the light emitted by the light source and receive reflected light from the workpiece; and
a processing system configured to determine the film thickness of the workpiece based on spectrum measurement data of the reflected light from the workpiece and preset spectrum data, the processing system being configured to:
determine reference spectrum data which is one of a plurality of preset spectra data acquired in the past;
create a latest preset spectrum data before polishing of the workpiece;
calculate a difference between the reference spectrum data and the latest preset spectrum data; and
determine that there is an abnormality in the latest preset spectrum data when the difference is larger than a threshold value.

13. The optical film-thickness measuring apparatus according to claim 12, wherein the difference is a Euclidean distance.

14. The optical film-thickness measuring apparatus according to claim 12, wherein the processing system is configured to:
classify the plurality of preset spectra data acquired in the past into groups according to algorithm of clustering; and
determine the reference spectrum data which is one selected from a plurality of normal preset spectra data belonging to one of the groups.

15. The optical film-thickness measuring apparatus according to claim 12, wherein the processing system is configured to:
normalize the plurality of preset spectra data acquired in the past to create a plurality of normalized preset spectra data; and
normalize the latest preset spectrum data to create a latest normalized preset spectrum data.

16. The optical film-thickness measuring apparatus according to claim 12, wherein each of the plurality of preset spectra data acquired in the past and the latest preset spectrum data is one of base intensity data containing reference intensity that provides a reference for intensity of reflected light from the workpiece, dark level data containing background intensity measured under a condition that light is cut off, and light monitoring data containing intensity of light of the light source for irradiating the workpiece.
